(19) United States
(12) Patent Application Publication
(10) Pub. No.: US 2016/0141534 A1
(43) Pub. Date: May 19, 2016

(54) METHOD FOR PRODUCING AN ACTIVE LAYER CAPABLE OF EMITTING AN ELECTRIC CURRENT UNDER IRRADIATION

(71) Applicants: ARKEMA FRANCE, Colombes (FR); UNIVERSITY DE BORDEAUX, Bordeaux (FR); CENTRE NATIONAL DE LA RECHERCHE SCIENTIFIQUE, Paris Cedex 14 (FR); INSTITUT POLYTECHNIQUE DE BORDEAUX, Talence Cedex (FR)

(72) Inventors: Christophe NAVARRO, Bayonne (FR); Guillaume FLEURY, Bordeaux (FR); Georges HADZIIOANNOU, Leognan (FR); Carine LACROIX, Bardos (FR); Eleni PAVLOPOULOU, Bordeaux (FR); Fabrice DOMINGUES DOS SANTOS, Paris (FR)

(73) Assignees: ARKEMA FRANCE, Colombes (FR); UNIVERSITY DE BORDEAUX, Bordeaux (FR); CENTRE NATIOANAL DE LA RECHERCHE SCIENTIFIQUE (CNRS), Paris Cedex 14 (FR); INSTITUT POLYTECHNIQUE DE BORDEAUX, Talence Cedex (FR)

(21) Appl. No.: 14/904,331

(22) PCT Filed: Jul. 10, 2014
(86) PCT No.: PCT/FR2014/051772

§ 371 Date: Jan. 11, 2016

(30) Foreign Application Priority Data
Jul. 11, 2013 (FR) 13.56832

(51) Int. Cl. H01L 51/42; H01L 51/00

(52) U.S. Cl. CPC H01L 51/42; H01L 51/0036; H01L 51/0043; H01L 51/0003

(57) ABSTRACT

The present invention relates to the field of organic electronics for photovoltaic energy, i.e. conversion of light energy into electricity. More particularly, this invention relates to a method of fabrication of an active layer capable of emitting an electric current under light irradiation combining a ferroelectric polymer material and a semiconducting polymer for converting light energy into electricity.

The present invention relates to the field of organic electronics for photovoltaic energy, i.e. the conversion of light energy into electricity. More particularly, this invention relates to a method for producing an active layer capable of emitting an electric current under irradiation, combining a ferroelectric material and a semiconducting polymer allowing light energy to be converted into electricity.

Devices already exist that allow light energy to be converted into electricity: photovoltaic cells. These devices consist of a cathode, an active layer and an anode. Photovoltaic cells can be made with inorganic materials or organic materials. Photovoltaic cells made from inorganic materials are well known; their efficiency is high, over 25%, but their cost of manufacture is high because inorganic materials are difficult to use. Organic materials have the advantage of being inexpensive, they are easy to use, and flexible devices can be obtained with these materials. However, low efficiencies are obtained using these materials, notably because of the way in which light energy is converted. The active layer of organic solar cells generally consists of P3HT (poly(3-hexylthiophene)) and PCBM ([6,6]-phenyl-C61-methyl butanoate). This organic active layer absorbs photons, and excitons, i.e. electron-hole pairs, are generated in the P3HT. It is necessary to separate these charges with an electric field that is higher than the Coulombic attraction between these two charges in order to obtain a photovoltaic current. Therefore it is the dissociation of these excitons and the transport of the free charges that will generate the photovoltaic current. The difference in energy level between P3HT and PCBM generates an internal electric field that makes it possible to dissociate the excitons created in the P3HT, and separation of the electron-hole pairs therefore takes place at the P3HT-PCBM interfaces. However, the efficiencies of organic photovoltaic cells are low, notably owing to excessive recombinations of the excitons, therefore we need to find another way of dissociating the excitons to increase the efficiency of organic photovoltaic cells.

Recent studies in the field of inorganic photovoltaic cells have investigated the photovoltaic effect generated by ferroelectric materials. Ferroelectric materials can be polarized when an electric field is applied that is greater than the coercive field, which is an intrinsic property of the material. Two states of polarization may thus be attained; when the material is no longer subjected to an external electric field, it conserves its polarization—this is remanent polarization. Fridkin et al., in their article with the title “Anomalous photovoltaic effect in ferroelectrics”, Soviet Physics Uspekhi, 1978, 21(12) p 981, describe the capacity of the ferroelectric material LiNbO₃ to generate a photocurrent and a photovoltaic current under illumination. It is therefore possible to utilize the ferroelectricity of certain inorganic materials in order to dissociate excitons. Choi et al., in their article with the title “Switchable ferroelectric diode and photovoltaic in BiFeO₃”, Science, 2009, 324, p 63, describe the use of the inorganic multiferroic material BiFeO₃. The state of polarization of BiFeO₃ allows separation of the electron-hole pairs created within the material. The current is higher under illumination, and BiFeO₃ therefore generates a photovoltaic current owing to ferroelectricity. Yang et al., in their article with the title “Above-band gap voltages from ferroelectric photovoltaic devices”, Nature nanotechnology, 2010, 5, p 143, also use BiFeO₃ and describe the mechanism responsible for the photovoltaic effect in this material.

Recent studies conducted on organic ferroelectric materials do not show such properties.

However, Yuan et al., in their article with the title “Efficiency enhancement in organic solar cells with ferroelectric polymers”, Nature Materials, 2011, 10, 296, describe the use of a small thickness of ferroelectric polymer P(VDF-TrFe) (poly(vinylidene fluoride-co-trifluoroethylene)) inserted between the active layer and the electrodes. It was demonstrated that the photovoltaic current increases on polarization of the ferroelectric polymer, and the polarization of this ferroelectric polymer therefore makes it possible to increase the efficiency of dissociation of the excitons. The P(VDF-TrFe) film may also be deposited between the two donor and acceptor materials of the active layer as described by Yang et al. in their article with the title “Tuning the energy level offset between donor and acceptor with ferroelectric dipole layers for increased efficiency in bilayer organic photovoltaic cells”, Advanced Materials, 2012, 24, 1455-1460. Current research on the use of ferroelectricity for photovoltaics concerns the capacity of the ferroelectric polymer PVDF-TrFe to increase the internal electric field so as to make dissociation of the excitons more efficient. However, the photovoltaic current is not induced solely by ferroelectricity, as there is concomitant presence of a donor/acceptor system.

Nalwa et al., in their article with the title “Enhanced charge separation in organic photovoltaic films doped with ferro electric dipole”, Energy Environ., 2012, 5, 7042-7049, describe a system where, in one example, the ferroelectric polymer is mixed with P3HT. However, the method of application by solvent evaporation and not by “spin casting” or “spin coating” from a solvent mixture is unlikely to give a fine distribution of the ferroelectric polymer within the P3HT matrix, but rather a macro-phase separation. The polarization of the ferroelectric polymer has little chance of being maintained as the ferroelectric polymer is only in contact with the semiconducting polymers. The charge density in the semiconducting polymers is too low and therefore cannot compensate the polarization of the ferroelectric material.

WO2010131254 discloses a method for producing photovoltaic cells based on a mixture of ferroelectric and semiconducting materials. However, this method comprises numerous steps for making the active layer that are very difficult to apply industrially and on a large scale. Moreover, no figure in this document is able to demonstrate the operation of this device and therefore its feasibility.

Moreover, the compositions of organic semiconducting materials and ferroelectric polymers mentioned in that application have little chance of leading to a notable photovoltaic effect. In particular, polymers such as PVDF and PTrFE are only ferroelectric after a physical treatment such as stretching, which is difficult to imagine in the compositions and associated morphologies described in that application.

Unexpectedly, the applicant observed that the electric field generated by a material capable of crystallizing in ferroelectric form is sufficient to dissociate the excitons for particular compositions, typically predominant amounts of the material capable of crystallizing in ferroelectric form combined with a simplified method of application. These compositions combine just one material capable of crystallizing in ferroelectric form with a semiconducting polymer within an unexpected morphology of the cylinder type of the semiconducting polymer and give excellent efficiency of photovoltaic conversion.

### SUMMARY OF THE INVENTION

The invention relates to a method for fabrication of a device comprising the following steps:
Preparing a solution comprising at least one solvent, material or mixture of materials capable of crystallizing in ferroelectric form and at least one semiconducting polymer, these compounds being miscible in said solvent for concentrations below 10 wt %, preferably below 5 wt %, the material or materials capable of crystallizing in ferroelectric form on the one hand and the conductive polymer or polymers on the other hand not being miscible with one another,
Spin coating, doctor blade coating or any other technique, of this solution on a conductive electrode,
Evaporating the solvent, in such a way that phase separation between the material or materials capable of crystallizing in ferroelectric form on the one hand and the semiconducting polymer or polymers on the other hand establishes a morphology.

### DETAILED DESCRIPTION

Any material or mixture of materials capable of crystallizing in ferroelectric form may be used in the invention. Preferably the material or mixture of materials capable of crystallizing in ferroelectric form are organic materials, and preferably polymers. It may also be a material capable of crystallizing in ferroelectric form and another material not necessarily capable of crystallizing in ferroelectric form when used alone, but on condition that the mixture of the two materials is capable of crystallizing in ferroelectric form.

The polymers or mixtures of polymers will preferably be selected that contain the monomeric entities vinylidene difluoride and trifluoroethylene, vinylidene difluoride and trifluoroethylene, vinylidene difluoride and hexafluoropropylene optionally with addition of a third monomer selected from the following monomers: trifluoroethylene, tetrafluoroethylene, vinyl fluoride, the perfluoroalkylvinyl ethers such as perfluoromethylvinyl ether, dichlorethylene, vinyl chloride, chlorotrifluoroethylene, perfluoro (methyl vinyl ether), bromotrifluoroethylene, tetrafluoropropene, hexafluoropropylene.

The odd polyamides such as PA7, PA9, PA11, PA13 may also be used, as well as mixtures thereof.

More particularly it is the copolymer of vinylidene with trifluoroethylene P(VDF-TrFe).

Any semiconductor material may be used in the invention. Preferably, the semiconductor material is an organic material, and more particularly a polymer. The conductive polymer may be an electron donor or an electron acceptor. It may also be a mixture of semiconducting polymers.

The semiconducting polymer is preferably selected from the polymers containing fluorenes, thiophenes, phenylenes, phenylene vinylidene, fullerenes, pyrilenes, carbazole, thiophene derivatives such as benzodithiophene or cyclopentadithiophene, fluorene derivatives, pyrrole and furan.

More preferably, the conductive polymer is poly(3-hexylthiophene) P3HT.

The mobilities of the semiconducting polymer are between 10⁻⁷ cm²/V⁻¹ s⁻¹ and 10⁴ cm²/V⁻¹ s⁻¹.

The invention also relates to a device comprising (a) a conductive electrode, (b) a second conductive electrode, (c) an active layer comprising a material capable of crystallizing in ferroelectric form and a semiconductor material, which separates the two electrodes on either side. Preferably the invention relates to a device comprising (a) a conductive transparent electrode, (b) a conductive metallic electrode, (c) an active layer comprising a material capable of crystallizing in ferroelectric form and a semiconductor material, which separates the two electrodes on either side.

According to one embodiment of the invention, in the device comprising (a) a conductive transparent electrode, (b) a conductive electrode, (c) an active layer comprising a material capable of crystallizing in ferroelectric form and a semiconductor material, which separates the two electrodes on either side, the material capable of crystallizing in ferroelectric form being polarized by mechanical deformation and/or by applying an electric field greater than the coercive field, and more preferably by applying an electric field greater than the coercive field, to the electrodes of the device.

Transparent electrode means an electrode whose transmittance is above 60% and preferably above 80%, for a thickness of the electrode of 100 nm, the transmittance being measured at 555 nm using a spectrophotometer, for example a lambda 19 spectrophotometer from the company Perkin Elmer.

Conductive electrode means an electrode whose conductivity is between 10 and 10⁹ S/cm.

The preferred compositions constituting the active layer are selected in such a way that the proportion of the material or materials capable of crystallizing in ferroelectric form is above 20 wt % relative to the total material capable of crystallizing in ferroelectric form and semiconducting polymer, and preferably above 50%, and more preferably between 70 and 95%.

Regarding the solvent required for preparing a solution comprising at least one solvent, material or mixture of materials capable of crystallizing in ferroelectric form and at least one semiconducting polymer, these compounds being miscible in said solvent for concentrations below 10 wt %, it is one or more polar and/or aromatic solvents capable of dissolving the ferroelectric polymer and the semiconducting polymer. The solvents will be selected from the following: tetrahydrofuran, methyl ethyl ketone, dimethylformamide, N,N-dimethylacetamide, diethylsulfoxide, acetone, methyl isobutyl ketone, cyclohexaxone, diacetone alcohol, diisobutyl ketone, butyrolactone, isophorone, 1,2-dimethoxyethane, chloroform, dichlorobenzene, ortho-dichlorobenzene.

Preparation of the active layer is carried out in such a way that phase separation of the two materials constituting the active layer leads to a morphology where one material is dispersed in the other material at a scale below μm, or has co-continuity of the two materials at a scale below μm. According to a variant of the invention, the types of morphologies mentioned above may also include the presence of a thin layer of the material or materials capable of crystallizing in ferroelectric form below 40 nm in contact with one or both electrodes.

According to a more preferred embodiment of the invention, preparation of the active layer is carried out in such a way that phase separation of the two materials constituting the active layer leads to a morphology of the cylinder type of the semiconducting polymer after evaporation of the solvent, with electrical contact of the semiconducting polymer phase and the phase of the material capable of crystallizing in ferroelectric form on the conductive electrode and an angle of the axis of the cylinders between 20 and 90° relative to the plane of the conductive electrode, and preferably between 70 and 90°, more preferably 90°, the layer thus deposited constituting said active layer after evaporation of the solvent.

The applicant also discovered that addition of additives to the ferroelectric material provides an additional advantage as it makes it possible to limit the electric field required for the polarization that is indispensable for operation of these devices. Among the additives, the plasticizers will be preferred, among which we may mention linear or branched phthalates such as the di-n-octyl, dibutyl, -2-ethylhexyl, diethylhexyl, diisononyl, diisodecyl, benzylbutyl, diethyl, dicyclohexyl, dimethyl, linear diundecyl, linear ditridecyl, phthalates, the chlorinated paraffins, the trimellitates, branched or linear, in particular diethylhexyl trimellitate, the aliphatic esters or the polymeric esters, the epoxides, adipates, citrates, benzoates, and these plasticizers may be used alone or combined.

These additives will be introduced in proportions ranging from 0.01 to 95% and preferably from 0.01 to 40% and more preferably from 0.1 to 10% relative to the sum of the mixture of materials capable of crystallizing in ferroelectric form.

These devices may possess remanent polarization following polarization of the material capable of crystallizing in ferroelectric form.

These devices are capable of producing an electric current under illumination.

The conductive and preferably transparent electrode may be of an organic or metallic nature. It may consist of carbon nanotubes. It may consist of semiconducting polymer such as PEDOT-PSS (poly(3,4-ethylenedioxythiophene)-poly(styrene sulfonate)).

It may also be hybrid, i.e. made partly of a mixture of organic and metallic material.

The devices resulting from the method of the invention are used in temperature ranges below the Curie point of the material or materials capable of crystallizing in ferroelectric form considered.

Preferably, these devices possess remanent polarization following polarization of the material capable of crystallizing in ferroelectric form.

These devices are advantageously used for producing electric current under illumination.

### EXAMPLE

The following device was used:
a glass substrate, on which an ITO (indium-tin oxide) electrode with a thickness of 100 nm is deposited.
an active layer comprising 90 wt % of P(VDF-TrFe) and 10 wt % of P3HT deposited by spin-coating on the ITO electrode from a 3 wt % solution of the two polymers in THF.
an LiF/Al electrode.

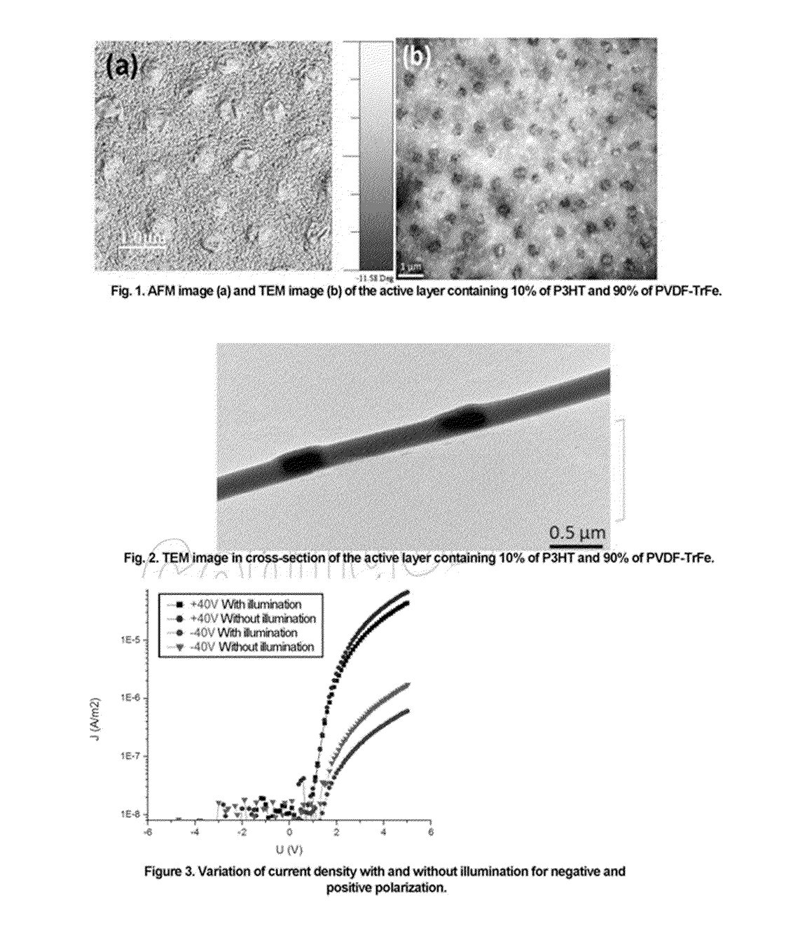

AFM and TEM images illustrate the morphology obtained (FIG. 1 and FIG. 2). The cylindrical distribution of the minority polymer (P3HT) (circles in FIG. 1(a)), and dark spots within the active layer (FIG. 2), can clearly be seen.

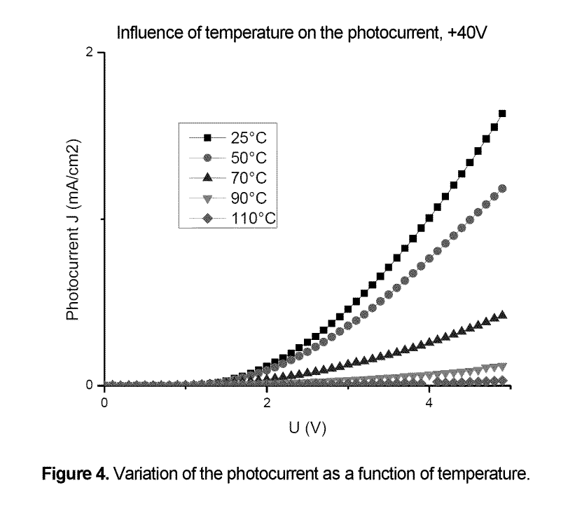

Under illumination, an increase in current of about 50% was observed (FIG. 3 and FIG. 4).

1. A method for fabrication of a device comprising the following steps:
preparing a solution comprising at least one solvent, a material or mixture of materials capable of crystallizing in ferroelectric form and at least one semiconducting polymer, the material or mixture of materials capable of crystallizing in ferroelectric form and the semiconducting polymer(s) being miscible in said solvent(s) to concentrations below 10 wt %, the material or materials capable of crystallizing in ferroelectric form on the one hand and the semiconducting polymer or polymers on the other hand not being miscible with one another,
coating the solution on a conductive electrode,
evaporating the solvent(s) from the solution, in such a way that phase separation between the material or materials capable of crystallizing in ferroelectric form on the one hand and the semiconducting polymer or polymers on the other hand establishes a morphology and an active layer is formed.

2. The method as claimed in claim 1 wherein a second conductive electrode, transparent or not, is deposited on the active layer previously formed.

3. The method as claimed in claim 2 in which the compositions constituting the active layer are selected in such a way that the proportion of the material or materials capable of crystallizing in ferroelectric form is above 20 wt % relative to the total amount of material or materials capable of crystallizing in ferroelectric form and semiconducting polymer.

4. The method as claimed in claim 3 in which preparation of the active layer is carried out in such a way that a cylinder morphology of the semiconducting polymer is established after evaporation of the solvent(s), with electrical contact of the semiconducting polymer phase and phase of material capable of crystallizing in ferroelectric form on the two electrodes and an angle of the axis of the cylinders between 20 and 90° relative to the plane of the electrodes.

5. The method as claimed in claim 4 in which one of the materials constituting the materials capable of crystallizing in ferroelectric form is a plasticizer.

6. The method as claimed in claim 5, wherein one of the materials capable of crystallizing in ferroelectric form is an organic material.

7. The method as claimed in claim 6, wherein the polymer material capable of crystallizing in ferroelectric form consists of a polymer or mixture of polymers containing fluorine.

8. The method as claimed in claim 7, wherein the polymer material capable of crystallizing in ferroelectric form is a copolymer of vinylidene fluoride and trifluoroethylene P(VDF-TrFe).

9. The method as claimed in claim 8, wherein the semiconducting polymer is an organic material containing fluorenes, thiophenes, phenylenes, vinylidene phenylenes, fullerenes, or pyrilenes.

10. The method as claimed in claim 9, characterized in that the semiconducting polymer is poly(3-hexylthiophene) P3HT.

11. The method of fabrication as claimed in claim 10 wherein the solvent or solvents comprises one or more polar and/or aromatic solvents capable of dissolving the ferroelectric polymer and the semiconducting polymer.

12. The method of fabrication as claimed in claim 11, wherein the solvent or solvents is selected from the group consisting of: tetrahydrofuran, methyl ethyl ketone, dimethylformamide, N,N-dimethylacetamide, diethylsulfoxide, acetone, methyl isobutyl ketone, cyclohexaxone, diacetone alcohol, diisobutyl ketone, butyrolactone, isophorone, 1,2-dimethoxyethane, chloroform, dichlorobenzene, and ortho-dichlorobenzene.

13. A photovoltaic device obtained using the method of claim 1.

14. The device as claimed in claim 13, where the material or materials capable of crystallizing in ferroelectric form is or are polarized by mechanical deformation and/or by applying an electric field greater than the coercive field to the electrodes of the device.

15. The device as claimed in claim 14, which has remanent polarization following polarization of the material or materials capable of crystallizing in ferroelectric form.

16. A method, comprising using a device as claimed in claim 13 to produce electric current under illumination.

17. The method as claimed in claim 5, wherein one of the materials capable of crystallizing in ferroelectric form is a polymer material.

18. The method as claimed in claim 6, wherein the polymer material capable of crystallizing in ferroelectric form consists of a copolymer containing vinylidene fluoride.

19. The method as claimed in claim 1, wherein the semiconducting polymer is poly(3-hexylthiophene) and the material capable of crystallizing in ferroelectric form is a copolymer of vinylidene fluoride and trifluoroethylene.

20. The method as claimed in claim 1, wherein the coating is carried out by spin coating or doctor blade coating.
